(19) United States
(12) Patent Application Publication
(10) Pub. No.: US 2008/0251927 A1
(43) Pub. Date: Oct. 16, 2008

(54) Electromigration-Resistant Flip-Chip Solder Joints

(75) Inventors: Jie-Hua Zhao, Plano, TX (US); Vikas Gupta, Dallas, TX (US); Kejun Zeng, Coppell, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 11/774,959

(22) Filed: Jul. 9, 2007

Related U.S. Application Data
(60) Provisional application No. 60/923,403, filed on Apr. 13, 2007.

(51) Int. Cl. H01L 21/31; H01L 21/44

(52) U.S. Cl. 257/762; 438/612; 257/E21.24; 257/E21.476

(57) ABSTRACT

A semiconductor device contact structure practically eliminating the copper diffusion into the solder as well as the current crowding at the contact with the subsequent electromigration in the solder. A column-like electroplated copper stud (108) is on each contact pad. The stud is sized to provide low, uniform electrical resistance in order to spread the current from the contact to an approximately uniform, low density. Preferably, the stud height (108a) is at least ten times the thickness of the copper interconnect layer (104). Stud (108) is capped by an electroplated nickel layer (109) thick enough (preferably about 2 μm) to suppress copper diffusion from stud (108) into solder body (120), thus practically inhibiting intermetallic compound formation and Kirkendall voiding.

### FIELD OF THE INVENTION

The present invention is related in general to the field of semiconductor devices and processes and more specifically to the structure and fabrication method of low cost, flip-chip solder joints, which are resistant against electromigration and void-causing intermetallic formation.

### DESCRIPTION OF THE RELATED ART

In the continuing trend to miniaturize integrated circuits, the RC time constant of the metal layer interconnection between the active circuit elements increasingly dominates the achievable IC speed-power product. Consequently, the relatively high resistivity of the traditional interconnecting aluminum layer has in recent years been replaced by the lower resistivity of copper layer.

In order to conserve silicon real estate, reduce device thickness and electrical resistance, semiconductor chips are increasingly assembled by flip-chip technology rather than wire bonding. In the flip-chip technology, it is common practice to interconnect the semiconductor chips with the help of solder bumps to external bodies such as substrates. Based on environmental concerns, the presently preferred tin-based solder does no longer contain lead.

It has recently been observed in large-scale tests of temperature cycling, solder re-melting, drop tests, and mechanical stress that the solder joints, especially in chips with copper interconnection layers, exhibit increasing failure rates due to solder joint cracks, as the power consumption of the devices is going up and at the same time the bump dimensions are going down. The data show that the number of failures increase with the number of solder reflows and with the amount of electrical current. The failures include cracks at the copper/solder interface, electrical opens, and the separation of the solder from the joint.

### SUMMARY OF THE INVENTION

Applicants conducted a metallurgical, statistical, and electrical analysis of the contact structures, coupled with computer modeling. The analysis of the contacts revealed that copper, which diffuses into the solder, reacts with the tin of the solder to form the intermetallic compounds Cu₃Sn at the interface copper/solder, followed by Cu₆Sn₅ towards the solder. Due to the different diffusion rates of copper and tin within the intermetallics, Kirkendall voids are formed at the intermetallic/solder interface.

The analysis of the solder contacts further revealed that an electrical current, which arrives at the contact from the high sheet resistance of the copper layer and has no chance to distribute to a lower resistance, remains crowded and causes large electromigration voids at the copper/solder joints. The electromigration driving force, in turn, enhances the Kirkendall void formation dramatically, further degrading the reliability of the joints.

The device structure according to the invention practically eliminates the copper diffusion into the solder as well as the current crowding at the contact with the subsequent electromigration in the solder. One embodiment of the invention has a semiconductor chip with copper layer interconnection and contact pads. A column-like electroplated copper stud is on each contact pad. The stud is sized to provide low, uniform electrical resistance in order to spread the current from the contact to an approximately uniform, low density. Preferably, the stud height is at least ten times the thickness of the copper interconnect layer.

The stud is capped by an electroplated nickel layer thick enough (preferably about 2 μm) to suppress copper diffusion. The nickel is in contact with a tin/silver solder bump, wherein the nickel layer blocks copper diffusion into the solder so that intermetallic compound formation and Kirkendall voiding are practically inhibited.

Another embodiment of the invention is a method for fabricating a semiconductor contact structure. The method starts with a semiconductor wafer, which has an interconnect layer of a thickness (preferably about 0.5 μm) near its surface; windows in the insulating overcoat over the wafer expose portions of the interconnect layer. A seed layer of a refractory metal followed by a seed layer of copper are deposited over the wafer, including the windows in the overcoat. Next, a photoresist layer is deposited over the copper seed layer, masked, developed, and etched to expose the copper seed layer portions in each window. Column-shaped studs of copper, between about 5 and 50μ high (preferably between 16 and 20 μm), are electroplated on the exposed copper seed layer portions. While the stud surfaces are still wet, a layer of nickel (preferably between 1.5 to 3.0 μm thick) is electroplated on the surface of each stud. For some devices, while the nickel surface is still wet, a body of solder (preferably 96.5 weight percent tin and 3.5 weight percent silver) is electroplated on the nickel layer. The photoresist and the exposed layers of refractory metal and copper seed are removed. For the devices with the plated solder, the solder body is reflowed to form an approximate solder ball.

The technical advances represented by certain embodiments of the invention will become apparent from the following description of the preferred embodiments of the invention, when considered in conjunction with the accompanying drawings and the novel features set forth in the appended claims.

### BRIEF DESCRIPTION OF THE DRAWINGS

FIG. 1 depicts a schematic cross section of an embodiment including a semiconductor chip with a contact structure of a copper stud covered by a nickel layer, and interconnecting tin/silver solder.

FIG. 2 shows the result of computer modeling of a contact structure without copper stud and nickel layer, illustrating current crowding at the contact perimeter due to high electrical resistance.

FIG. 3 shows the result of computer modeling of a contact structure with copper stud and nickel layer, illustrating the low and approximately uniform current density in the interconnecting solder.

FIGS. 4 through 10 illustrate steps of a method for fabricating flip-chip solder joints resistant against electromigration and Kirkendall voids.

FIG. 4 shows the steps of depositing seed layers of refractory metals and copper and of a photoresist layer, followed by opening a window in the photoresist layer to expose a portion of the copper seed layer.

FIG. 5 illustrates the step of electroplating a column-shaped copper stud on the exposed copper seed layer.

FIG. 6 shows the step of electroplating a layer of nickel of the copper stud.

FIG. 7 shows the step of electroplating a body of solder on the nickel layer.

FIG. 8 depicts the steps of removing the photoresist layer.

FIG. 9 shows the step of removing the copper seed layer not covered by the stud.

FIG. 10 illustrates the step of reflowing the solder body.

### DETAILED DESCRIPTION OF THE PREFERRED EMBODIMENTS

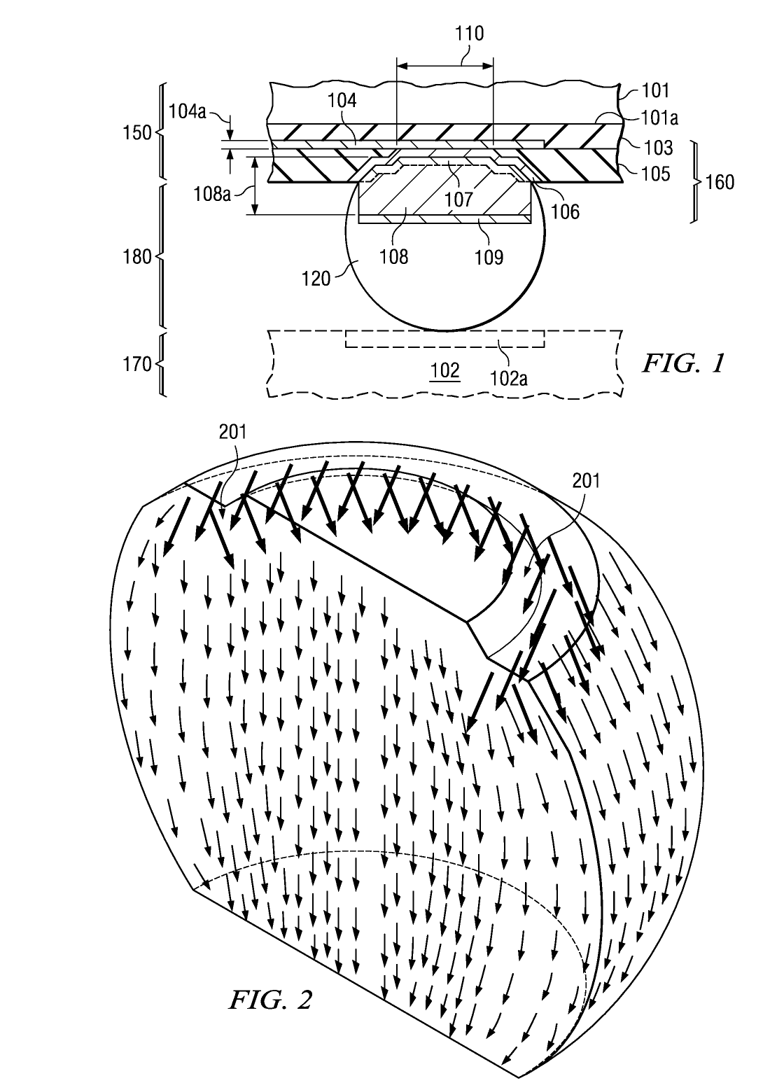

FIG. 1 illustrates an embodiment of the invention including a portion of a semiconductor chip 150, a structured contact pad 160 of the chip, and a solder ball 120 intended for electrical connection to external parts 170. The connection of contact pad 160 and solder 170 is reliable under the conditions of both accelerated stress tests and lifetime device operation, since the connection is structured to suppress electromigration as well as intermetallic formation and Kirkendall voiding.

In FIG. 1, the semiconductor material 101 has a surface 101a, which is covered by an interlevel dielectric layer (ILD) 103. The ILD may include silicon dioxide or mechanically weak materials of low dielectric constant such as silicon-containing hydrogen silsesquioxane. The thickness of layer 103 may vary widely (from 20 to 1000 nm), but is typically quite uniform across the wafer diameter. On the outward-facing surface of ILD layer 103 is an interconnect trace 104, which is a patterned interconnect layer preferably made of copper; alternatively, it may be made of an aluminum alloy. The thickness 104a of the patterned layer 104 is in the range between about 0.4 to 0.6 μm, preferably about 0.5 μm. Interconnect trace 104 may be deposited on the surface of ILD layer 103, or may consume a portion of the layer 103 thickness. The combined thickness of trace 104 and dielectric layer 103 may range from about 1 to 15 μm.

Trace 104 and the remainder of layer 103 are overlaid by an insulating protective overcoat 105, which preferably includes silicon nitride, silicon oxynitride, or a stack of silicon nitride and silicon dioxide in a thickness range between about 0.5 and 1.0 μm; overcoat 105 is practically impenetrable to moisture.

FIG. 1 shows a window of width 110 opened in overcoat 105 to expose the metal surface of trace 104 in the window. Throughout the window 110, the exposed trace portion 104 as well as the sidewalls of window are covered with a refractory barrier layer 106. Preferred metal choices for the barrier layer include titanium, tungsten, chromium, or alloys thereof; the preferred thickness range of layer 106 is between about 400 and 600 nm.

As FIG. 1 shows, in contact with the refractory layer 106 is a copper seed layer 107 merged with a column-shaped stud 108 of electroplated copper. The width of the stud may vary; a preferred width is 18 μm. The height 108a of the stud is preferably at least ten times the thickness 104a of the patterned interconnect layer. Consequently, the column height 108a of the copper stud is preferably between about 5 and 50 μm.

As a result, height 108a provides the copper stud 108 with a low electrical resistance. Due to the low resistance of the stud, an electrical current can spread readily and pass through the stud in an approximately uniform density, entering the solder body 120 while practically avoiding the crowding of current. As an example for the contact pads of many device types, a copper stud with a height between 5 and 50 μm provides an electrical resistance low enough to spread a 1 A current to an approximately uniform current density of less than 3·10E8 pA/μm². (The processes of electroplating the copper and subsequent metals are described below).

Without copper stud 108 and nickel layer 109 at contact window 110, the electrical current, arriving in the chip metallization, enters the contact window with pronounced current crowing around the window perimeter and causes high current densities in the solder, resulting in electromigration in the joint-near regions of the solder. This current crowding 201 in conventional technology is illustrated in FIG. 2 by computer modeling of the current flow in the solder body; the maximum current density is 1.12E9 pA/μm².

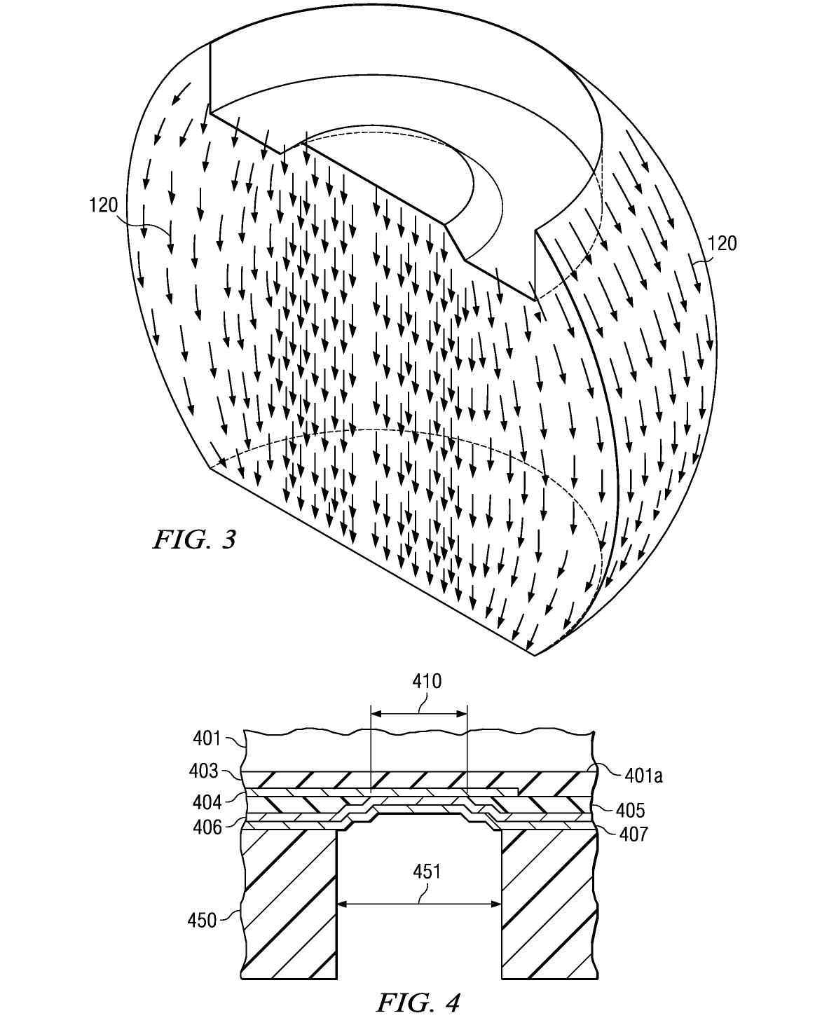

In contrast, the computer modeling in FIG. 3 shows the electrical current flow in solder body 120 of a contact joint with the copper stud 108 and the nickel layer 109. The low electrical resistance of the copper stud provides a more uniform current distribution for entering the solder, resulting in almost one order of magnitude lower current density in the solder, the maximum current density being only 3.34E8 pA/μm². Since the meantime-to-failure of a contact is proportional to the inverse of the square of the current density, the reduction of current density according to the invention translates into an improved solder joint reliability by many orders of magnitude.

Electrical modeling can further be applied to determine the width 110 of the contact window and the height 108a of stud 108 required to provide an approximately uniform current flow and density for avoiding current crowding.

FIG. 1 illustrates that a layer 109 of nickel is on the surface of copper stud 108. The nickel is electroplated to a layer thickness between about 1.5 and 3.0 μm; the preferred nickel layer thickness is 2 μm. This thickness range is suitable to suppress copper diffusion from stud 108 into the solder body 120.

As depicted in FIG. 1, a body 120 of solder is in contact with nickel layer 109; the solder is preferably deposited by electroplating (see below). The preferred solder has a composition of 96.5 weight percent tin and 3.5 weight percent silver. The plated solder body 120 is in contact with the plated first nickel layer 109 directly without intermediate metal layers. Based on the specifics of the reflow process, the shape of solder body 120 may vary; FIG. 1 illustrates an approximately spherical shape. This shape will obviously be modified in the attachment process to external parts.

As stated, nickel layer 109 suppresses the diffusion of copper from stud 108 into solder 120. Consequently, the subsequent formation of tin-copper intermetallic compounds and the appearance of Kirkendall voids in the solder body are also suppressed.

The low electrical resistance of copper stud 108 and thus the approximately uniform current density provide the preconditions for a current flow through the solder body 120 so that electromigration in the solder can be minimized. As a result, the formation of the large voids in the solder region close to the joint, which are usually a consequence of electromigration, is practically eliminated. Together with the elimination of Kirkendall voids by preventing the copper diffusion into the solder, the reliability of the solder joint is at least an order of magnitude improved.

Referring to FIG. 1, the external part 170, indicated by dashed outlines, may be a substrate with an insulating core material 102 integral with one or more layers of metal including a metal contact pad 102a. Alternatively, the external part 170 may be a portion of a metal leadframe, or another semiconductor chip with a metal contact pad.

After the assembly of chip 150 onto external part 170 in a solder reflow process, it may be advisable to fill the gap 180 between chip 150 and part 170 with a polymer underfill material or a molding compound in order to reduce thermo-mechanical stress in the solder joint.

Another embodiment of the invention is a method for fabricating a semiconductor contact structure resistant against electromigration voids and Kirkendall voids. FIGS. 4 through 9 illustrate steps of the method, which uses a whole semiconductor wafer, while the Figures depict only a portion of the wafer. In FIG. 4, the surface 401a of wafer 401 includes a structure of an insulating layer 403 (preferably made of silicon dioxide or a low-k dielectric) and a patterned interconnect layer 404, preferably made of copper (or alternatively made of an aluminum alloy). The metal layer has a thickness between about 0.4 and 0.6 μm, preferably about 0.5 μm. The insulator-and-conductor structure is overlaid by an insulating overcoat 405, preferably a moisture resistant insulator such as silicon nitride or silicon oxynitride. Of the plurality of windows opened in the overcoat to expose portions of the interconnect layer 404, FIG. 4 shows only window 410.

In the next process step, a seed layer 406 of refractory metal such as titanium, tungsten, or both, followed by a seed layer 407 of copper are deposited over the wafer overcoat, with the copper layer being the outermost layer. A preferred thickness for the refractory layer is about 300 nm, and for the copper layer between about 200 and 800 nm. The preferred method is a sputtering technique, wherein the depositions are performed in one pump-down. The seed layers provide a uniform bias potential across the wafer for the following electroplating steps.

Next, a layer 450 of photoresist is deposited over the copper seed layer. The photoresist is masked, developed and etched to create openings 451 for exposing the copper seed layer portions in each opening, whereby the photoresist openings 451 are aligned with the overcoat windows 410.

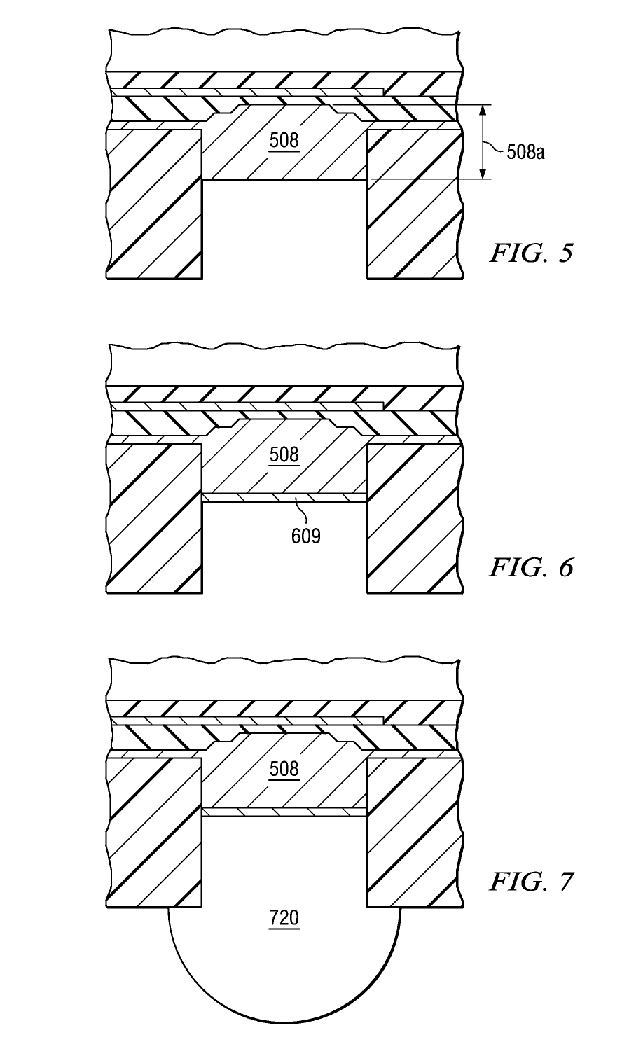

In the next process step, illustrated in FIG. 5, a stud 508 of copper, shaped as a column, is electroplated on each exposed copper seed layer portion. The height 508a of the plated stud is preferably at least ten times the thickness of the patterned interconnect layer 404 and may vary from about 5 to 50 μm. Preferably, the height 508a of the stud is between about 16 to 20 μm.

Then, while the surface of copper stud 508 is still wet, a layer 609 of nickel is electroplated on the surface of each stud 508. This deposition is illustrated in FIG. 6. Nickel layer 609 has a thickness preferably between about 1.5 and 2.5 μm.

In the preferred process flow, the next step, illustrated in FIG. 7, is performed while the surface of nickel layer 609 is still wet. The step involves the electroplating of a body 720 of solder on the nickel layer. Preferably, the solder includes 96.5 weight percent tin and 3.5 weight percent silver. The amount of solder, or the volume of body 720, which can be deposited, is mostly determined by the pitch center-to-center of adjacent copper studs 508. In many devices the thickness of the plated solder ranges from about 5 to 40 μm.

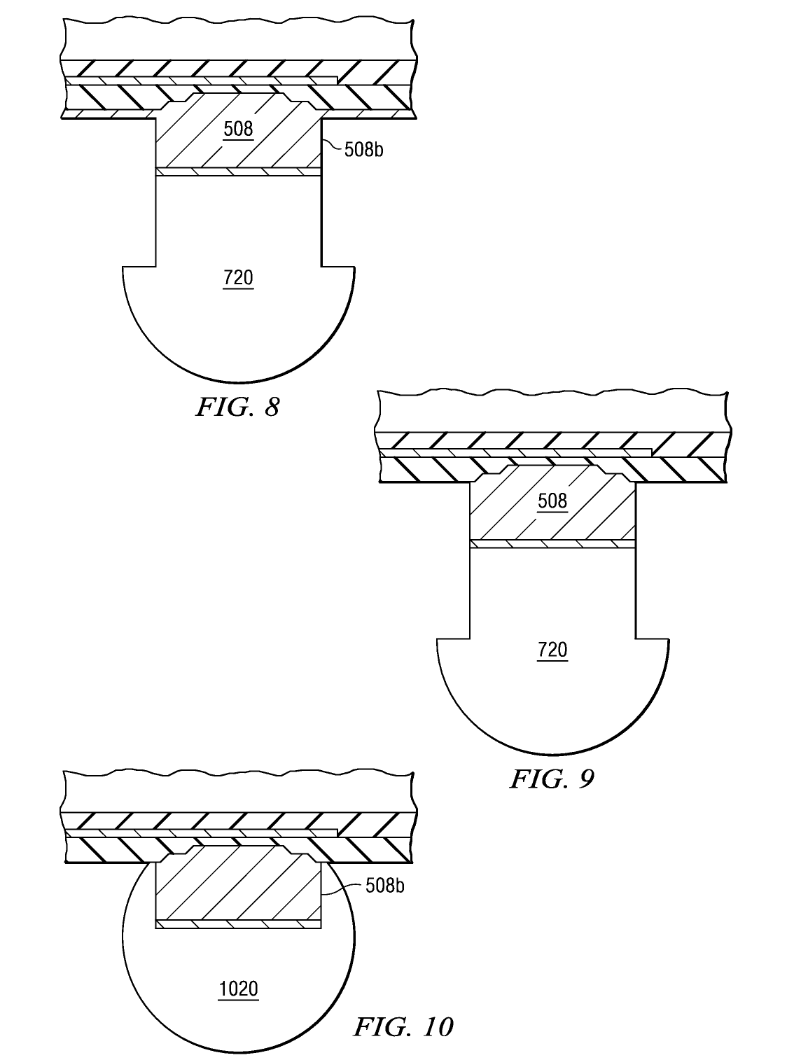

FIG. 8 shows the structure after the step of removing the photoresist layer. This removal exposes the sides 508b of copper stud 508. FIG. 9 illustrates the structure after the step of removing the seed layer of refractory metal and the seed layer of copper, which have not been covered by copper stud 508. Finally, FIG. 10 depicts the step of reflowing solder body 720 to form an approximate solder ball 1020. In this step, the molten solder is wetting the sides 508b of stud 508 so that large parts of sides 508b become covered with solder. FIG. 10 is analogous to FIG. 1.

An alternative to the electroplating step of solder is the application of solder paste, as discussed in FIG. 3. This alternative is preferred in devices, in which the semiconductor chip is interconnected to metal leads (instead to insulating substrates).

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type and any number of semiconductor chips, discrete or integrated circuits, and the material of the semiconductor chip may comprise silicon, silicon germanium, gallium arsenide, or any other semiconductor or compound material used in integrated circuit manufacturing. It is therefore intended that the appended claims encompass any such modifications or embodiment.

We claim:

1. An apparatus comprising:
a semiconductor chip having a surface including a patterned interconnect layer of a thickness overlaid by an insulating overcoat;
a window in the overcoat to expose a portion of the interconnect layer;
a layer of refractory metal in contact with the exposed metal throughout the window;
a column-shaped stud of electroplated copper in contact with the refractory metal; and
a layer of electroplated nickel on the copper stud.

2. The apparatus according to claim 1 further including a body of electroplated solder in contact with the nickel layer.

3. The apparatus according to claim 2 further including a substrate having a metal contact pad in contact with the solder body.

4. The apparatus according to claim 1 wherein the patterned interconnect layer includes copper and has a thickness of about 0.5 μm.

5. The apparatus according to claim 1 wherein the copper stud has a height of at least ten times the thickness of the patterned interconnect layer.

6. The apparatus according to claim 5 wherein the column of the copper stud has a height between about 5 and 50 μm.

7. The apparatus according to claim 5 wherein the copper stud has an electrical resistance low enough to spread a 1 A current to an approximately uniform current density of less than 3·10E8 pA/μm².

8. The apparatus according to claim 7 wherein the approximately uniform current density minimizes the formation of electromigration voids.

9. The apparatus according to claim 1 wherein the solder includes 96.5 weight percent tin and 3.5 weight percent silver.

10. The apparatus according to claim 1 wherein the plated solder body is in contact with the plated nickel layer directly without intermediate metal layers.

11. The apparatus according to claim 1 wherein the nickel layer has a thickness in the range from about 1.5 to 3.0 μm.

12. A method for fabricating a semiconductor contact structure comprising the steps of:
providing a semiconductor wafer having a surface including a patterned interconnect layer of a thickness overlaid by an insulating overcoat, and a plurality of windows in the overcoat to expose portions of the interconnect layer;
depositing a seed layer of a refractory metal followed by a seed layer of copper over the wafer overcoat;
depositing a layer of photoresist over the copper seed layer;
masking, developing and etching the photoresist to create openings for exposing the copper seed layer portions in each opening;
electroplating column-shaped studs of copper on the exposed copper seed layer portions;
then electroplating, while the stud surfaces are still wet, a layer of nickel on the surface of each stud;
removing the photoresist; and
removing the refractory metal seed layer and the copper seed layer not covered by the stud.

13. The method according to claim 12 further including, after the step of electroplating the nickel layer and before the step of removing the photoresist, the step of electroplating, while the nickel surface is still wet, a body of solder on the nickel layer.

14. The method according to claim 13 wherein the solder includes 96.5 weight percent tin and 3.5 weight percent silver.

15. The method according to claim 13 further including, after the step of removing the seed layer, the step of reflowing the solder body to form an approximately spherical solder ball.

16. The method according to claim 12 wherein the patterned interconnect layer of the chip includes copper of about 0.5 μm thickness.

17. The method according to claim 12 wherein the refractory metal includes titanium, tungsten, or both.

18. The method according to claim 12 wherein the step of depositing the refractory metal seed layer and the copper seed layer includes a sputtering technique in one pump-down.

19. The method according to claim 12 wherein the copper seed layer has a thickness in the range from about 200 to 800 nm.

20. The method according to claim 12 wherein the copper stud has the shape of a column with a height between about 5 to 50 μm.

21. The method according to claim 12 wherein the copper stud has a height between about 16 to 20 μm.

22. The method according to claim 12 wherein the nickel layer has a thickness in the range from about 1.5 to 2.5 μm.
